(19) United States
(12) Patent Application Publication
(10) Pub. No.: US 2015/0364448 A1
(43) Pub. Date: Dec. 17, 2015

(54) PACKAGE STRUCTURE

(71) Applicant: IBIS Innotech Inc., Taichung City (TW)

(72) Inventors: Chih-Kung Huang, Taichung City (TW); Wei-Jen Lai, Taichung City (TW); Wen-Chun Liu, Taichung City (TW)

(21) Appl. No.: 14/663,450

(22) Filed: Mar. 19, 2015

(30) Foreign Application Priority Data
Jun. 13, 2014 (TW) 103120581

(51) Int. Cl. H01L 25/065; H01L 21/78; H01L 21/768; H01L 23/31; H01L 23/522; H01L 23/498; H01L 23/552; H01L 21/56; H01L 23/00

(52) U.S. Cl. CPC H01L 25/0657; H01L 21/561; H01L 21/568; H01L 21/78; H01L 21/768; H01L 24/03; H01L 24/96; H01L 24/06; H01L 23/5226; H01L 23/49827; H01L 23/49838; H01L 24/17; H01L 23/552; H01L 23/3107; H01L 2224/03462; H01L 2924/01046; H01L 2924/01024; H01L 2924/01029; H01L 2224/03552; H01L 2224/16055; H01L 2224/16057; H01L 2224/16238; H01L 2224/08146; H01L 2225/06541; H01L 2225/06548; H01L 2225/06517; H01L 2225/06555

(57) ABSTRACT

A package structure includes a chip, a selective-electroplating epoxy compound, a patterned circuit layer and a plurality of conductive vias. The chip includes a plurality of solder pads, an active surface and a back surface opposite to the active surface. The solder pads are disposed on the active surface. The selective-electroplating epoxy compound covers the chip and includes non-conductive metal complex. The patterned circuit layer is disposed directly on a surface of the selective-electroplating epoxy compound. The conductive vias are disposed directly at the selective-electroplating epoxy compound to electrically connect the solder pads and the patterned circuit layer.

### CROSS-REFERENCE TO RELATED APPLICATION

This application claims the priority benefit of Taiwan application serial no. 103120581, filed on Jun. 13, 2014. The entirety of the above-mentioned patent application is hereby incorporated by reference herein and made a part of this specification.

### BACKGROUND OF THE INVENTION

1. Field of the Invention

The invention relates to a package structure, and particularly relates to a package structure that a patterned circuit layer is selectively formed on an epoxy compound.

2. Description of Related Art

In the information society nowadays, people by degrees tend to rely on electronic products. To cope with the requirements of high speed, excellent performance, and being light, thin, and compact on the electronic products nowadays, flexible circuit boards having flexibility are more commonly applied in various electronic products, such as mobile phones, notebook PCs, digital cameras, tablet PCs, printers, and disk players, etc.

Generally speaking, a package structure is principally manufactured by stacking a plurality of dielectric layers with respect to each other, and performing a pretreatment, sputtering, and copper-laminating or copper-electroplating on surfaces of the dielectric layers, and then performing a lithography process to form circuit layers and conductive vias on the surfaces of the dielectric layers. However, the processes in the manufacturing method are complicated and the cost of sputtering is relatively high. Moreover, it is challenging for a patterned circuit layer formed by using a patterned dry film as an electroplating barrier to meet the requirement of fine pitch nowadays. Besides, the dielectric layers are usually formed of materials such as polyimide, prepreg (PP), or Ajinomoto build-up film (ABF) resin, which have a higher cost. Therefore, the package structures not only require to be manufactured in complicated processes but also have a high cost. In view of the above, the invention discloses how to use a selective-electroplating epoxy compound as a dielectric layer and selectively electroplate to form a patterned circuit layer on the dielectric layer. The patterned circuit layer formed by selective-electroplating is disposed under the surface of the dielectric layer or be thickened through electroplating to protrude out of the surface of the dielectric layer. Moreover, the invention discloses how the technique is applied to the package structure, thereby providing a solution to this industry.

### SUMMARY OF THE INVENTION

The invention provides a package structure that is manufactured by a simplified manufacturing method and offers a greater flexibility to circuit design as compared to the conventional art.

A package structure according to the embodiments of the invention includes a first chip, a first selective-electroplating epoxy compound, a first patterned circuit layer, and a plurality of first conductive vias. The first chip includes a plurality of first solder pads, an active surface, and a back surface opposite to the active surface. In addition, the first solder pads are disposed on the active surface. The first selective-electroplating epoxy compound covers the first chip and includes a non-conductive metal complex. The first patterned circuit layer is directly disposed on a surface of the first selective-electroplating epoxy compound, and the first selective-electroplating epoxy compound exposes an upper surface of the patterned circuit layer. The upper surface is lower than or coplanar with the surface of the first selective-electroplating epoxy compound. The first conductive vias are disposed in the first selective-electroplating epoxy compound to electrically connect the first solder pads to the first patterned circuit layer.

Based on the above, the embodiments of the invention exploit the selective-electroplating characteristic of the selective-electroplating epoxy compound, and are capable of forming conductive structures such as the patterned circuit layer and the conductive vias, etc. by directly performing electroplating on the surface of the selective-electroplating epoxy compound. In addition, the selective-electroplating epoxy compound includes non-conductive metal complex. Therefore, after selectively irradiating the selective-electroplating epoxy compound, electroplating may be selectively performed on the surface of the selective-electroplating epoxy compound to form conductive structures such as the patterned circuit layer, conductive vias, or pads, etc. Moreover, the patterned circuit layer formed by selective-electroplating may be located under the surface of the selective-electroplating epoxy compound, or protrude from the surface of the selective-electroplating epoxy compound by thickening the patterned circuit layer through electroplating to provide greater electric flux. Therefore, the selective-electroplating epoxy compound is applicable for various kinds of package structures to form a circuit layer on the selective-electroplating epoxy compound by exploiting the characteristic thereof. Moreover, the patterned circuit layer not only meets the fine pitch requirement, but also provides flexibility in designing circuits in the package structure. Thus, the package structure according to the embodiments of the invention is not only manufactured by a simplified manufacturing method, but also offers flexibility in designing the patterned circuit layer of the package structure. Moreover, the patterned circuit layer also meets the fine pitch requirement.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1D are schematic views illustrating a manufacturing method of a package structure according to an embodiment of the invention.

FIG. 2 is a cross-sectional schematic view illustrating a package structure according to an embodiment of the invention.

FIG. 3 is a cross-sectional schematic view illustrating a package structure according to an embodiment of the invention.

FIGS. 4-15 are cross-sectional schematic views illustrating package structures according to different embodiments of the invention.

FIGS. 16-18 are schematic views illustrating a manufacturing method of a package structure according to an embodiment of the invention.

FIG. 19 is a schematic view illustrating a manufacturing method of a package structure according to an embodiment of the invention.

FIGS. 20-24 are cross-sectional schematic views illustrating package structures according to different embodiments of the invention.

FIG. 25 is a schematic view illustrating a manufacturing method of a package structure according to an embodiment of the invention.

FIGS. 26-27 are cross-sectional schematic views illustrating package structures according to different embodiments of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

It is to be understood that both of the foregoing and other detailed descriptions, features, and advantages are intended to be described more comprehensively by providing embodiments accompanied with figures hereinafter. In the following embodiments, wordings used to indicate directions, such as “up,” “down,” “front,” “back,” “left,” and “right”, merely refer to directions in the accompanying drawings. Therefore, the directional wording is used to illustrate rather than limit the present invention. In addition, like or similar elements are referred to by using like or similar reference numerals.

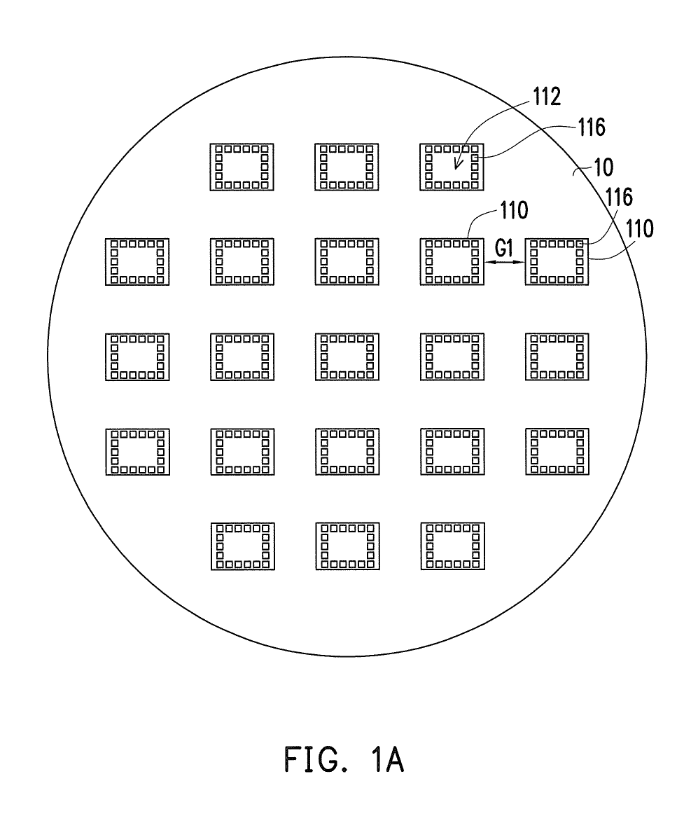

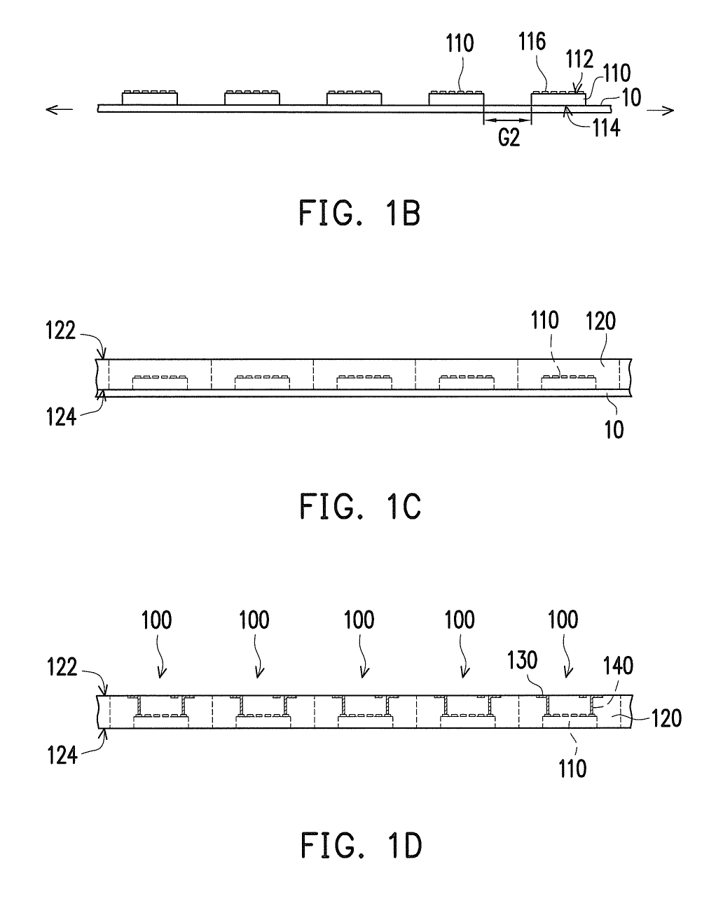

FIGS. 1A to 1D are schematic views illustrating a manufacturing method of a package structure according to an embodiment of the invention. It should be noted that FIG. 1A is a top schematic view illustrating the manufacturing method of the package structure, while FIGS. 1B to 1D are cross-sectional schematic views illustrating the manufacturing method of the package structure. The manufacturing method of the package structure according to the embodiment includes steps as follows. First of all, a plurality of first chips 110 are disposed on a release film 10. Each of the first chips 110 includes a plurality of solder pads 116, an active surface 112, and a back surface 114 opposite to the active surface 112. The first solder pads 116 are disposed on the active surface 112, a first gap G1 exists between any two adjacent chips 110, as shown in FIG. 1A. The release film 10 of this embodiment may be a heat-resistant release film. Then, referring to FIG. 1B, the release film 10 is stretched in a direction from the center to the periphery of the release film 10 to extend the release film 10, such that a second gap G2 exists between any two adjacent chips 110, and the second gap G2 is greater than the first gap G1. In other words, the gap between two adjacent chips 110 is increased by stretching and extending the release film 10 for the convenience of the subsequent patterned circuit layer formation and singularization processes. Then, referring to FIG. 1C, a first selective-electroplating epoxy compound 120 is formed on the release film 10 to cover the first chips 110. In this embodiment, the first chips 110 are adhered to the release film 10 with the back surfaces 114, and the first selective-electroplating epoxy compound 120 covers the first active surfaces 112 and the first solder pads 116 of the first chips 110. Then, referring to FIG. 1D, the release film 10 is removed to expose the back surface 114 of each of the first chips 110.

Then, a selective-electroplating characteristic of the first selective-electroplating epoxy compound 120 may be exploited to directly form a first patterned circuit layer 130 on a surface of the first selective-electroplating epoxy compound 120. Specifically, selective-electroplating is directly performed on the selective-electroplating epoxy compound 120 in this embodiment to form the fine-pitch patterned circuit layer 130. In this embodiment, the first selective-electroplating epoxy compound 120 contains non-conductive metal complex, and the non-conductive metal complex may include palladium, chromium and copper complex.

Specifically speaking, the surface of the first selective-electroplating epoxy compound 120 may be selectively electroplated to form the first patterned circuit layer 130 and a first conductive via 140. The forming step includes: a part of a surface 122 of the first selective-electroplating epoxy compound 120 for forming the first patterned circuit layer 130 is selectively irradiated by laser, such that the non-conductive metal complex in the irradiated part of the first selective-electroplating epoxy compound 120 is destructed to release heavy metal nuclei which is highly active in metal reduction, and then a metal reduction process is performed to the irradiated part of the first selective-electroplating epoxy compound 120 to selectively electroplate the irradiated part, so as to form the first patterned circuit layer 130 on the irradiated part of the first selective-electroplating epoxy compound 120. Of course, the embodiment described herein only is merely an example, and the invention is not limited thereto.

Meanwhile, the same method may be applied in this embodiment to directly form the plurality of first vias 140 on the first selective-electroplating epoxy compound 120, such that the first conductive vias 140 connect the first solders pads 116 of each of the first chips 110 to the corresponding first patterned circuit layer 130. Accordingly, multiple package structures 100 are formed. Then, the multiple package structures 100 shown in FIG. 1D are singularized. Namely, a cutting process is performed along broken lines shown in FIG. 1D to obtain the plurality of package structures 100 independent from each other.

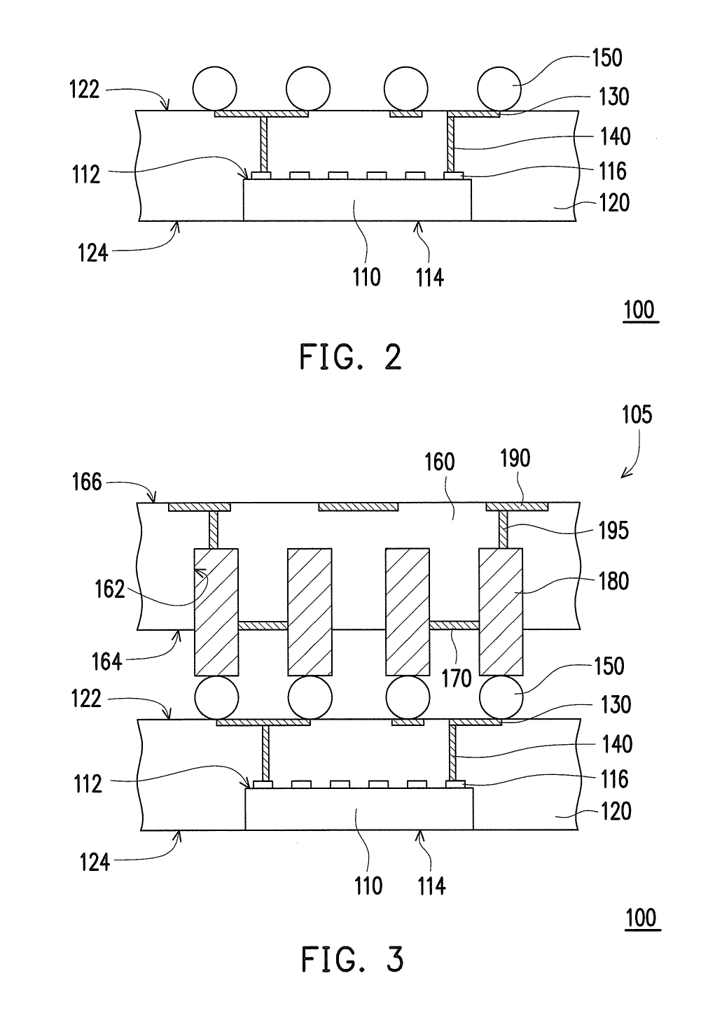

FIG. 2 is a cross-sectional schematic view illustrating a package structure according to an embodiment of the invention. The package structure 100 manufactured according to the manufacturing method described above includes the first chip 110, the first selective-electroplating epoxy compound 120, the first patterned circuit layer 130, and the plurality of first conductive vias 140, as shown in FIG. 2. The first chip 110 includes the plurality of first solder pads 116, the active surface 112, and the back surface 114 opposite to the active surface 112. The first solder pads 116 are disposed on the active surface 112. The first selective-electroplating epoxy compound 120 covers the first chip 110 and includes the non-conductive metal complex. The first patterned circuit layer 130 is directly disposed on the surface of the first selective-electroplating epoxy compound 120. Specifically, the first selective-electroplating epoxy compound 120 includes a third surface 122 and a fourth surface 124 opposite to each other. In this embodiment, the first patterned circuit layer 130 is disposed on the third surface 122. The first conductive vias 140 are directly disposed on the first selective-electroplating epoxy compound 120 to electrically connect the first solder pads 116 to the first patterned circuit layer 130 on the third surface 122.

FIG. 3 is a cross-sectional schematic view illustrating a package structure according to an embodiment of the invention. More specifically, the package structure may 100 further include an interposer 105, and the interposer 105 may include a second selective-electroplating epoxy compound 160, a second patterned circuit layer 170, a plurality of metal posts 180, a plurality of pads 190, and a plurality of second conductive vias 195. A material of the second selective-electroplating epoxy compound 160 is substantially the same as that of the first selective-electroplating epoxy compound 120, and the second selective-electroplating epoxy compound 160 also includes the non-conductive metal complex. Thus, in the package structure 100, the selective-electroplating characteristic of the second selective-electroplating epoxy compound 160 may also be exploited to directly form the second patterned circuit layer 170, the second conductive vias 195, and the pads 190 on a surface of the second selective-electroplating epoxy compound 160. As shown in the drawings, the second selective-electroplating epoxy compound 160 includes a plurality of cavities 162, a first surface 164, and a second surface 166 opposite to the first surface 164. The cavities 162 are disposed on the first surface 164. The second patterned circuit layer 170 is directly disposed on the first surface 164 by selective-electroplating, so as to be electrically connect with the corresponding metal posts 180.

Moreover, the metal posts 180 are respectively disposed in the cavities 162 and protrude out of the first surface 164. The pads 190 are directly disposed on the second surface 166 by selective-electroplating, and the second conductive vias 195 are directly disposed in the second selective-electroplating epoxy compound 170 to electrically connect the pads 190 to the corresponding metal posts 180. In this embodiment, the package structure 100 may further include a plurality of solder balls 150. The solder balls 150 are disposed between the metal posts 180 and the third surface 122 and are electrically connected to the first patterned circuit layer 130, such that the first chip 110 is electrically connected to the metal posts 180 of the interposer 105 through the solder balls 150. Accordingly, the package structure 100 may be electrically connected to an external electronic device (e.g. a motherboard) through the pads 190.

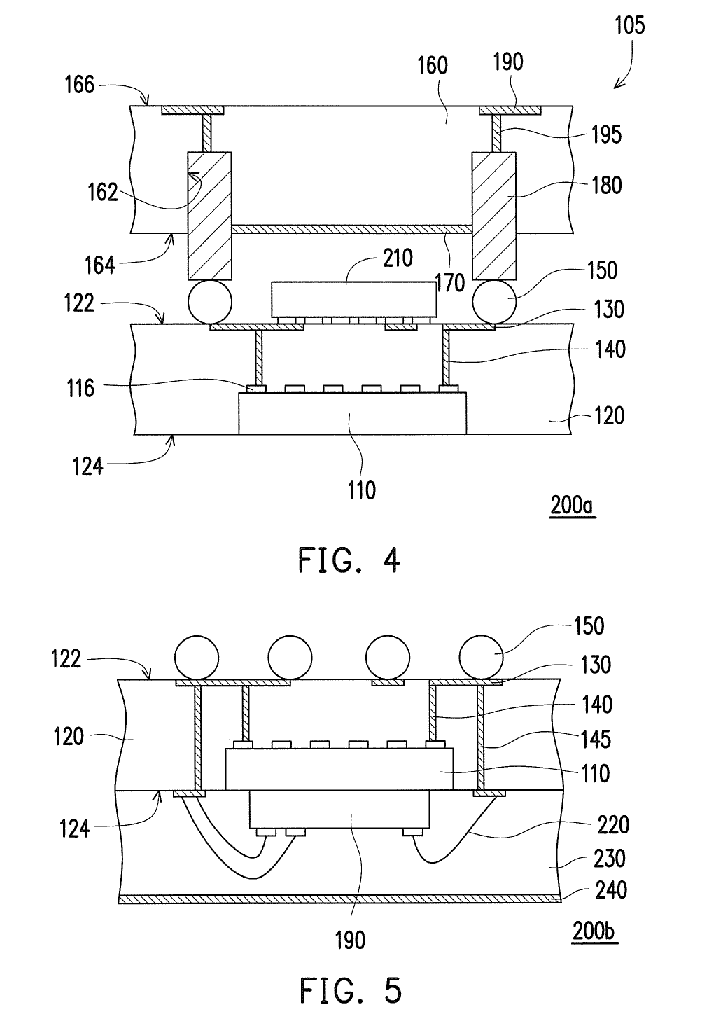

FIGS. 4-15 are cross-sectional schematic views illustrating package structures according to different embodiments of the invention. Referring to FIG. 4, a package structure 200a of this embodiment further includes a second chip 210 disposed on the third surface 122 of the first selective-electroplating epoxy compound 120 and electrically connected to the first patterned circuit layer 130. Specifically, the second chip 210 is disposed on the third surface 122 of the first selective-electroplating epoxy compound 120 through flip-chip bonding, and is electrically connected to the first patterned circuit layer 130 located on the third surface 122. The second chip 210 may be located between the solder balls 150. The solder balls 150 are connected between the metal posts 180 and the third surface 122, and are electrically connected to the first patterned circuit layer 130. Then, the first chip 110 and the second chip 210 may be electrically connected to the metal posts 180 of the interposer 105 through the solder balls 150, for example.

Referring to FIG. 5, it should be noted that a package structure 200b of this embodiment is similar to the package structure 200a of FIG. 4. Therefore, the reference numerals and a part of the contents in the previous embodiment are used in the following embodiments, in which like reference numerals refer to like or similar elements and repeated description of the same technical contents is omitted. For a detailed description of the omitted parts, reference can be made to the previous embodiment, and no repeated description is contained in the following embodiments. Description with respect to the difference between the package structure 200b of this embodiment and the package structure 200a of FIG. 4 is provided below.

The second chip 210 of this embodiment is disposed on the fourth surface 124 of the first selective-electroplating epoxy compound 120. Specifically speaking, the package structure 200b of this embodiment further includes a plurality of wires 220, a plurality of third conductive vias 145, and an encapsulant 230. As shown in FIG. 5, the third conductive vias 145 penetrate the first selective-electroplating 120 to connect the fourth surface 124 of the first selective-electroplating epoxy compound 120 and the first patterned circuit layer 130 on the third surface 122. The second chip 190 is stacked on the first chip 110 in a back-to-back configuration and is located on the fourth surface 124. Then, the second chip 190 is electrically connected to the third conductive vias 145 through the wires 220. Subsequently, the encapsulant 230 is disposed to cover the second chip 190 and the wires 220. In this embodiment, the encapsulant 230 may have the same component as the selective-electroplating epoxy compounds 120 and 160 or may be a conventional encapsulant.

In addition, in the package structure, electroplating may be directly performed on an outer surface of the first selective-electroplating epoxy compound 120 or the encapsulant 230 to form a shielding metal layer 240 shown in FIG. 5. The shielding metal layer 240 completely covers the outer surface of the first selective-electroplating epoxy compound 120 or the encapsulant 230 for reducing noise coupling of electric field and for electromagnetic shielding. In this embodiment, the shielding metal layer 240 may be further connected to a ground electrode to provide a more desirable electromagnetic shielding effect.

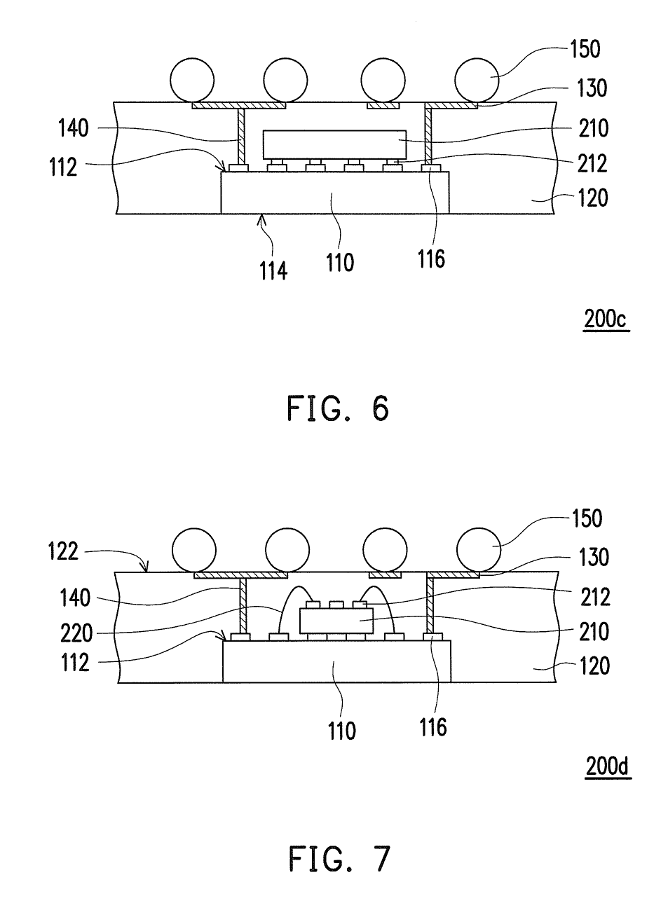

Referring to FIG. 6, similar to the previous embodiments, a package structure 200c of this embodiment also includes the second chip 210, and the second chip 210 includes a plurality of second solder pads 212. The second chip 210 of this embodiment is stacked on the active surface 112 of the first chip 110. In other words, the second chip 210 is stacked on the first chip 110 in a face-to-face configuration, and the second chip 210 is electrically connected to the first solder pads 116 through the second solder pads 212, and the first selective-electroplating epoxy compound 120 also covers the second chip 210.

Continuing to refer to FIG. 7, similar to the embodiments above, a package structure 200d of this embodiment also includes the second chip 210, and the second chip 210 also includes the plurality of second solder pads 212. However, the second chip 210 of this embodiment is stacked on the active surface 112 of the first chip 110 with a back surface not having the second solder pads 212. In other words, the second chip 210 is stacked on the first chip 110 in a back-to-face configuration. The second solder pads 212 are electrically connected to at least a part of the first solder pads 116 through the wires 220. Moreover, the first selective-electroplating epoxy compound 120 also covers the second chip 210 and the wires 220. The first conductive vias 140 connect remaining of the first solder pads 116 to the third surface 122, such that the first chip 110 and the second chip 210 can be further electrically connected to, for example, the metal posts 180 of the interposer 105 through a current conductive path formed by the first conductive via 140, the first patterned circuit layer 130, and the solder balls 150.

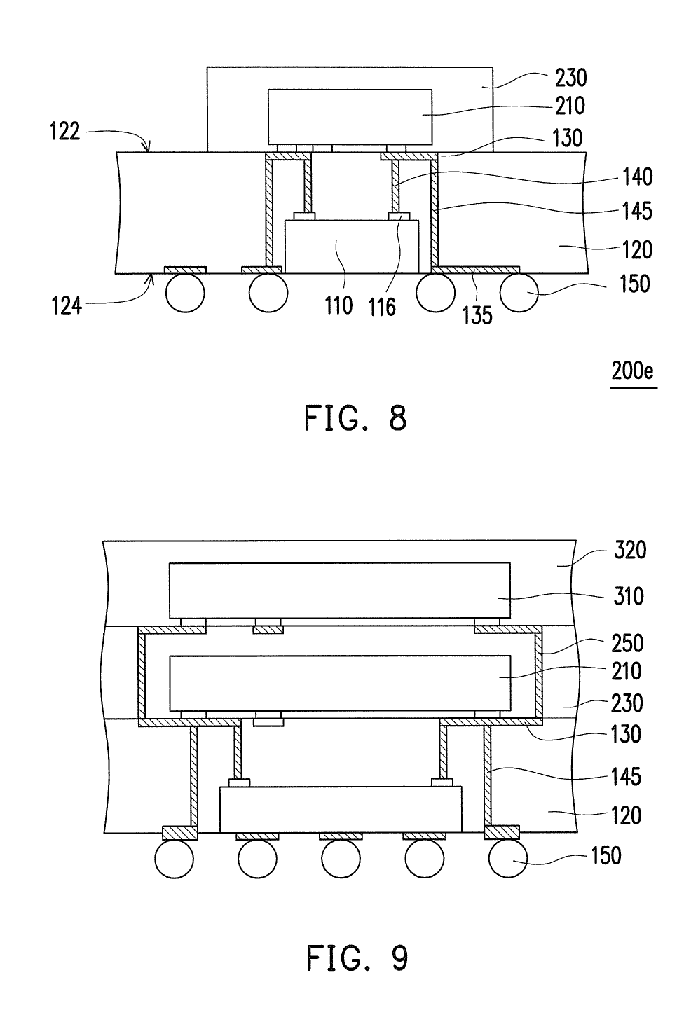

Of course, in an embodiment of the invention, the solder balls 150 may not be disposed on the third surface 122 of the first selective-electroplating epoxy compound 120, but be disposed on the fourth surface 124 of the first selective-electroplating epoxy compound 120 as shown in FIG. 8. The first patterned circuit layer 130 is directly disposed on the third surface 122, as previously described, and electrically connected to the first conductive vias 140. Under such configuration, a package structure 200e may further include a third patterned circuit layer 135 and a third conductive via 145, as shown in FIG. 8. Same as the first patterned circuit layer 130, the third patterned circuit layer 135 is also directly formed on the fourth surface 124 of the first selective-electroplating epoxy compound 120 by selective-electroplating process. The third conductive via 145 penetrates the first selective-electroplating epoxy compound 120 to connect the first patterned circuit layer 130 and the third patterned circuit layer 135. The solder balls 150 are disposed on the fourth surface 124 and electrically connected to the third patterned circuit layer 135. Accordingly, the metal posts 180 of the interposer 105 may be disposed on the fourth surface 124 of the first selective-electroplating epoxy compound 120 through the solder balls 150.

Moreover, the package structure 200e of this embodiment may further include the second chip 210 and the encapsulant 230. The second chip 210 may be disposed on the third surface 122 and electrically connected to the first patterned circuit layer 130, and the encapsulant 230 covers the second chip 210. In this embodiment, the encapsulant 230 may have the same component as that of the selective-electroplating epoxy compounds 120 and 160 or may be a conventional encapsulant. Thus, the first chip 110 and the second chip 210 may be electrically connected to the metal posts 180 of the interposer 105 through a current conductive path formed by the first conductive via 140, the third conductive via 145, the first patterned circuit layer 130, the third patterned circuit layer 135, and the solder balls 150.

Of course, a third chip 310 may be further stacked on an upper surface of the encapsulant 230 in this embodiment, as shown in FIG. 9. Similar to the way the second chip 210 is disposed, the third chip 310 may be electrically connected to the first patterned circuit layer 130 through a conductive via 250 penetrating the encapsulant 230. In addition, an encapsulant 320 covers the third chip 310. The embodiment does not intend to limit a number of stacked layers and a configuration of electrical connection of the package structure.

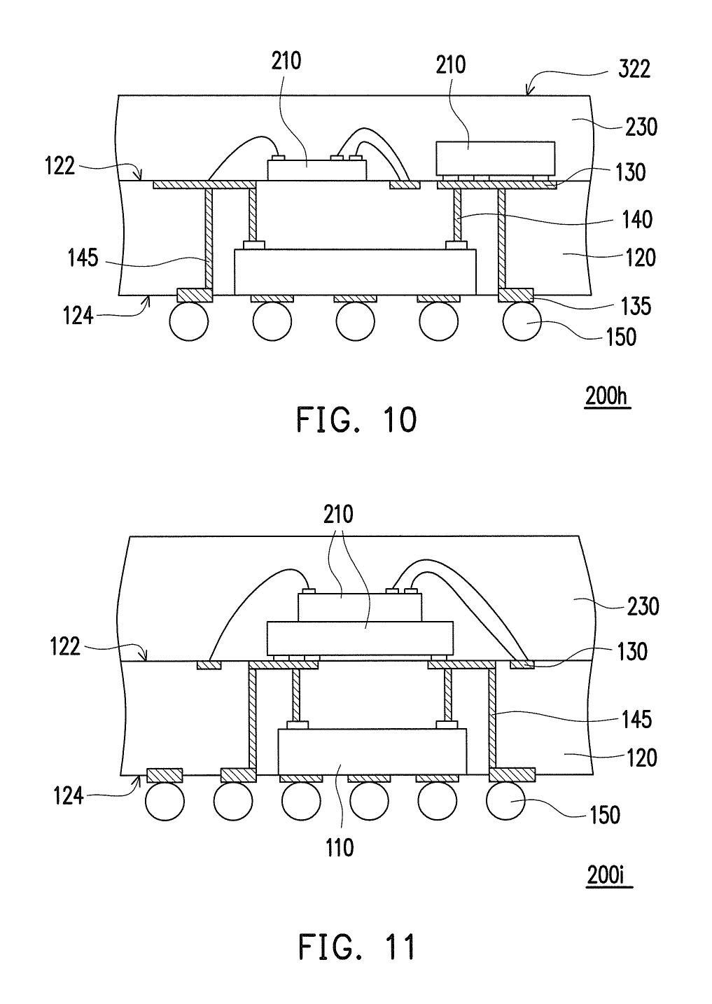

Referring to FIG. 10, a package structure 200h of this embodiment may include at least one second chip 210 (two second chips 210 are shown in the figure, but the invention is not limited thereto), and a third selective-electroplating epoxy compound 230. The second chips 210 may be disposed on the third surface 122 and electrically connected to the first patterned circuit layer 130, and the third selective-electroplating epoxy compound 230 covers the second chips 210. In this embodiment, the third selective-electroplating epoxy compound 230 may have the same component as that of the selective-electroplating epoxy compounds 120 and 160. Therefore, the selective-electroplating characteristic may be exploited for directly electroplating to form a patterned circuit layer or a conductive via on the third selective-electroplating epoxy compound 230. Alternatively, the third selective-electroplating epoxy compound 230 may be a conventional encapsulant. In this embodiment, each of the second chips 210 may be electrically connected to the first patterned circuit layer 130 through wire bonding or flip-chip bonding. FIG. 10 is merely shown as an example, instead of limiting the configuration of electrical connection of the invention.

In addition, the plurality of second chips 210 may be disposed on the third surface 122 by being stacked with respect to each other, as shown in FIG. 11. The second chip 210 closest to the third surface 122 may be electrically connected to the first patterned circuit layer 130 by flip-chip bonding, for example, and the second chip 210 away from the third surface 122 may be electrically connected to the third patterned circuit layer 130 through wire bonding, for example. However, FIG. 11 is merely shown as an example, instead of limiting a configuration of electrical connection of the second chip 210 of the invention.

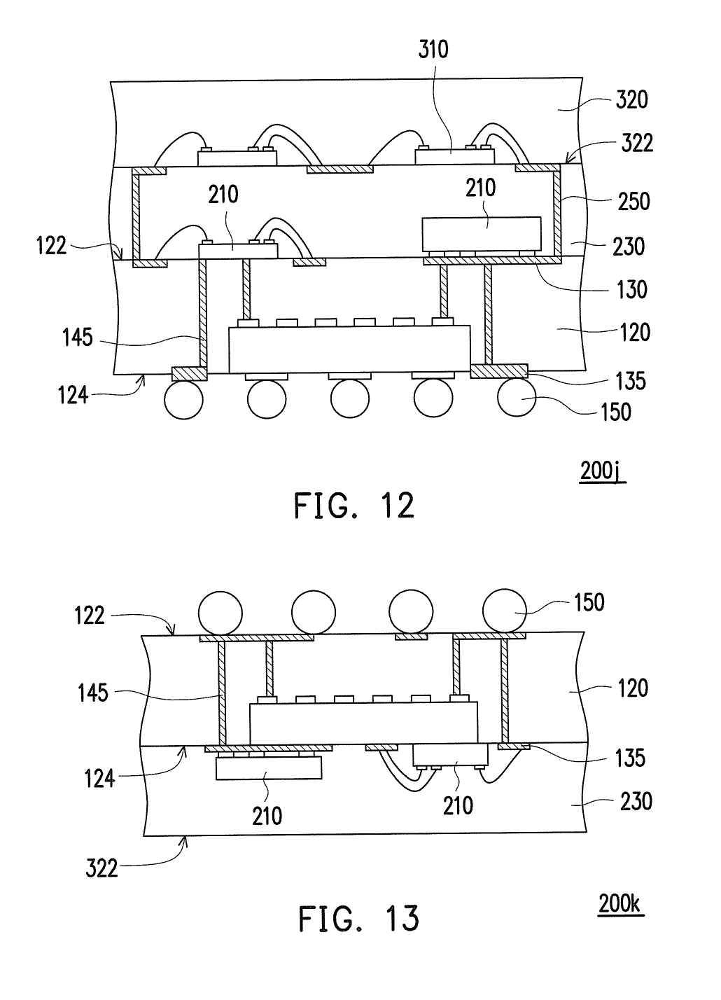

Continuing to refer to FIG. 12, a package structure 200j of this embodiment may further include at least one third chip 310 (two third chips 310 are shown in the figure, but the invention is not limited thereto), and the third chips 310 are disposed on a fifth surface 322 of the third selective-electroplating epoxy compound 230. Specifically, the third selective-electroplating epoxy compound 230 includes the fifth surface 322 opposite to a surface of the third selective-electroplating epoxy compound 230 covering the third surface 122, and the third chips 310 are disposed on the fifth surface 322. Moreover, the package structure 200j of this embodiment further includes a plurality of fourth conductive vias 250 penetrating the third selective-electroplating epoxy compound 230 to electrically connect the first patterned circuit layer 130 to the fifth surface 322. Accordingly, the third chips 310 may be disposed on the fifth surface 322 and may be electrically connected to the fourth conductive vias 250 by wire bonding or flip-chip bonding, for example. However, FIG. 12 is merely shown as an example, instead of limiting a configuration of electrical connection of the third chip 310 of the invention. The package structure of this embodiment may be electrically connected to a motherboard through the solder balls 150, for example. However, the invention is not limited thereto.

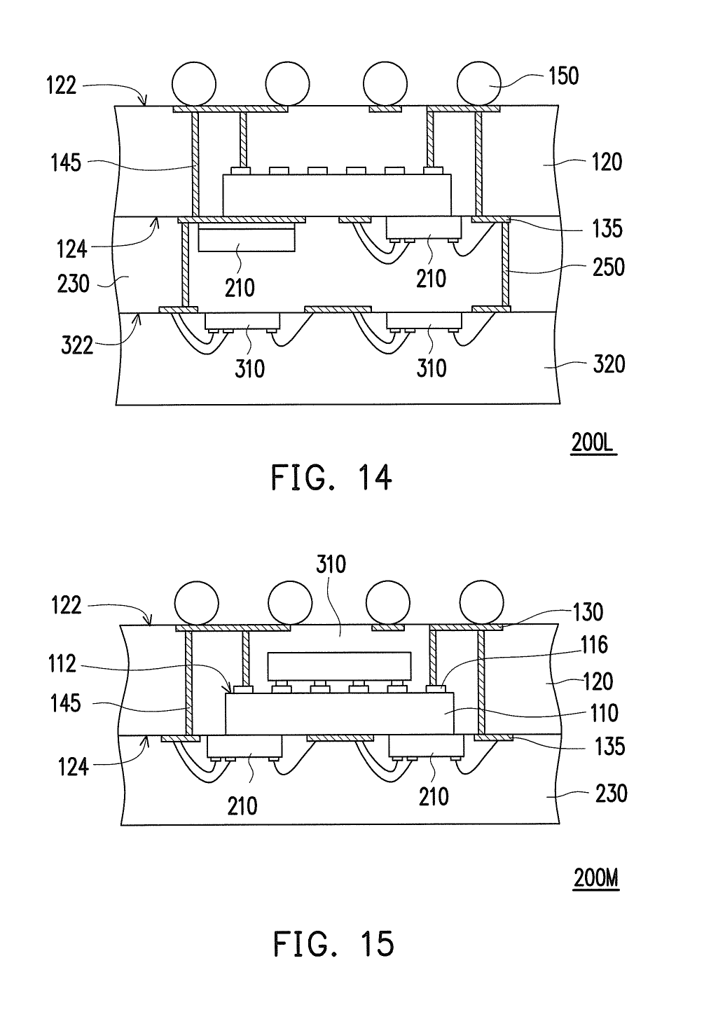

Referring to FIG. 13, different from the embodiments shown in FIGS. 10 to 12, the second chips 210 of this embodiment are disposed on the fourth surface 124 and electrically connected to the third patterned circuit layer 135. In addition, the third selective-electroplating epoxy compound 230 covers the second chips 210. In this embodiment, the third selective-electroplating epoxy compound 230 may have the same component as that of the selective-electroplating epoxy compounds 120 and 160. Therefore, the selective-electroplating characteristic may be exploited for directly electroplating to form a patterned circuit layer or a conductive via on the third selective-electroplating epoxy compound 230. Alternatively, the third selective-electroplating epoxy compound 230 may be a conventional encapsulant. In this embodiment, each of the second chips 210 may be electrically connected to the third patterned circuit layer 135 by wire bonding or flip-chip bonding. FIG. 13 is merely shown as an example, instead of limiting the configuration of electrical connection of the invention.

Continuing to refer to FIG. 14, a package structure 200L of this embodiment may further include at least one third chip 310 (two third chips 310 are shown in the figure, but the invention is not limited thereto), and the third chips 310 are disposed on the third selective-electroplating epoxy compound 230. The third selective-electroplating epoxy compound 230 covers the second chip 210 and the fourth surface 124. Specifically, the third selective-electroplating epoxy compound 230 includes the fifth surface 322 opposite to a surface of the third selective-electroplating epoxy compound 230 covering the fourth surface 124, and the third chips 310 are disposed on the fifth surface 322. Moreover, the package structure 200L of this embodiment further includes the plurality of fourth conductive vias 250 penetrating the third selective-electroplating epoxy compound 230 to electrically connect the third patterned circuit layer 135 to the fifth surface 322. Accordingly, the third chips 310 may be disposed on the fifth surface 322 and electrically connected to the fourth conductive vias 250 by wire bonding or flip-chip bonding, for example. However, FIG. 14 is merely shown as an example, instead of limiting a configuration of electrical connection of the third chip 310 of the invention. Then, the package structure of this embodiment may be electrically connected to a motherboard through the solder balls 150, for example. However, the invention is not limited thereto.

Referring to FIG. 15, a package structure 200M shown in FIG. 13 may further include at least one third chip 310. The third chip 310 may be disposed on the active surface 112 of the first chip 110 by flip-chip bonding, for example, and the third chip 310 may be electrically connected to the first solder pads 116. In addition, the first selective-electroplating epoxy compound 120 also covers the third chip 310. Of course, in other embodiments of the invention, the third chip 310 disposed on the active surface 112 of the first chip 110 may also be electrically connected to the first solder pads 116 by wire bonding, for example. Alternatively, the third chip 310 may be plural and stacked with respect to each other on the active surface 112 of the first chip 110. The third chip 310 close to the active surface 112 may be electrically connected to the first solder pads 116 by flip-chip bonding, for example, and the third chip 310 away from the active surface 112 may be electrically connected to the first solder pads 116 by wire bonding, for example. However, FIG. 15 is merely shown as an example, instead of limiting a configuration of electrical connection of the third chip 310 of the invention.

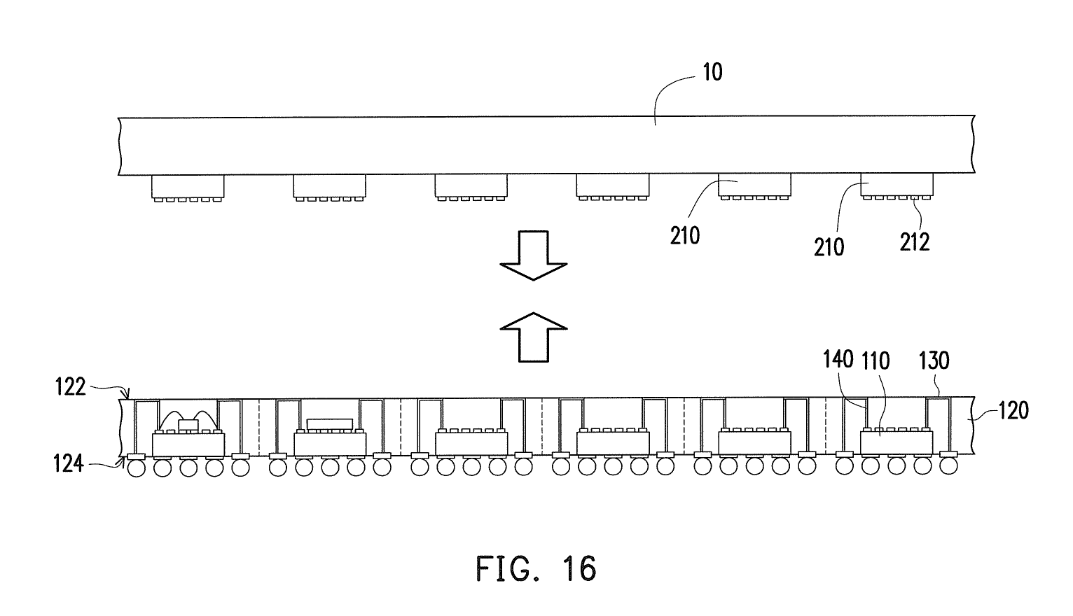

FIGS. 16-18 are schematic views illustrating a manufacturing method of a package structure according to an embodiment of the invention. It should be noted that FIG. 16 illustrates a method for disposing the second chip 210 shown in FIG. 8 on the third surface 122 of the first selective-electroplating epoxy compound 120, and the method includes steps as follows. First of all, as shown in FIG. 16, an array package structure is provided. The array package structure includes the plurality of first chips 110, the first selective-electroplating epoxy compound 120, the plurality of first patterned circuit layers 130, and the plurality of first conductive vias 140. In this embodiment, the first selective-electroplating epoxy compound 120 covers the first chips 110. The first patterned circuit layers 130 are directly disposed on the third surface 122 of the first selective-electroplating epoxy compound 120 and are electrically connected to the corresponding first chips 110 through the corresponding first conductive vias 140. The plurality of second chips 210 may be adhered to the release film 10 with the back surfaces not having the second solder pads 212. Each of the second chips 210 includes the plurality of solder pads 212, the active surface, and the back surface opposite to the active surface. The solder pads 212 are disposed on the active surface, and each of the second chips 210 is disposed on the release film 10 with the back surface thereof. Similar to the embodiment shown in FIGS. 1A to 1C, the first gap initially exists between any two adjacent second chips 210. Then, the release film 10 is stretched in the direction from the center to the periphery of the release film 10 to extend the release film 10, such that the second gap exists between any two adjacent second chips 210, and the second gap is greater than the first gap, so as to make it convenient for the subsequent patterned circuit layer formation and singularization processes. Then, the second chips 210 are laminated to the corresponding third surface 122 of the first selective-electroplating epoxy compound 120 by using the release film 10, and the second solder pads 212 and the first patterned circuit layer 130 on the third surface 122 are electrically connected. Then, the release film 10 is removed, and the singularization process is performed. Namely, the first selective-electroplating epoxy compound 120 is cut along broken lines shown in FIG. 16 to form a plurality of independent package structures.

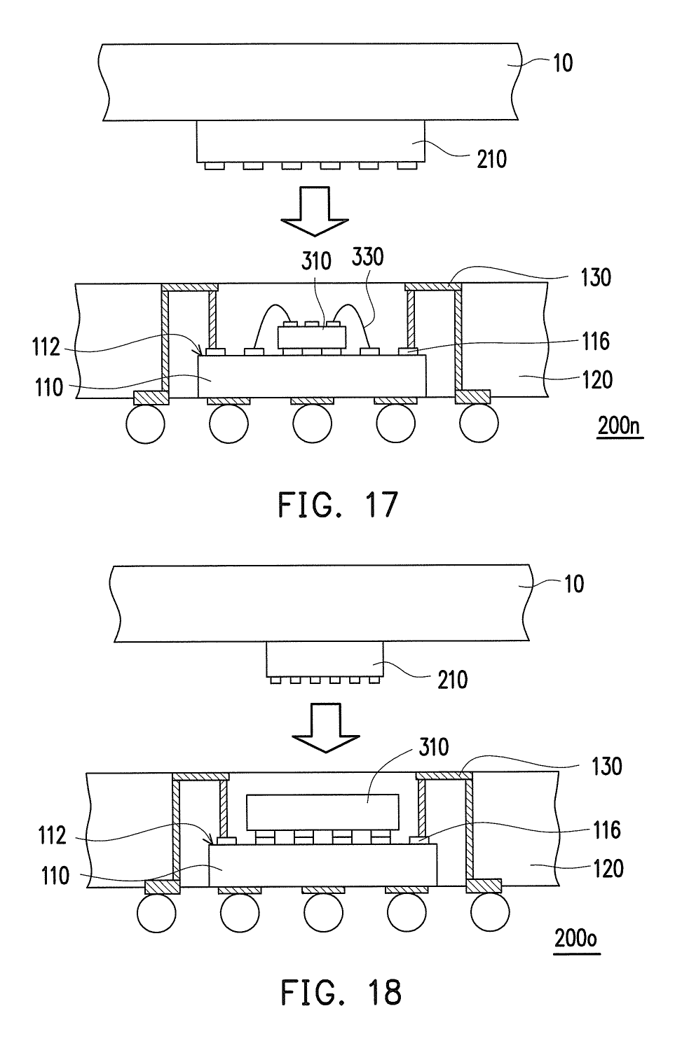

In addition, similar to the aforementioned manufacturing method, in the package structure shown in FIG. 17, a package structure 200n may further include the third chip 310 disposed on the active surface 112 of the first chip 110 and is electrically connected to the first solder pads 116 through the wires 330. The first selective-electroplating epoxy compound 120 also covers the third chip 310. Similarly, in the package structure shown in FIG. 18, the third chip 310 of a package structure 200o is also stacked on the active surface 112 of the first chip 110 in the face-to-face configuration. In other words, the third chip 310 is electrically connected to the first solder pads 116 by using the solder pads thereof, and the first selective-electroplating epoxy compound 120 also covers the third chip 310.

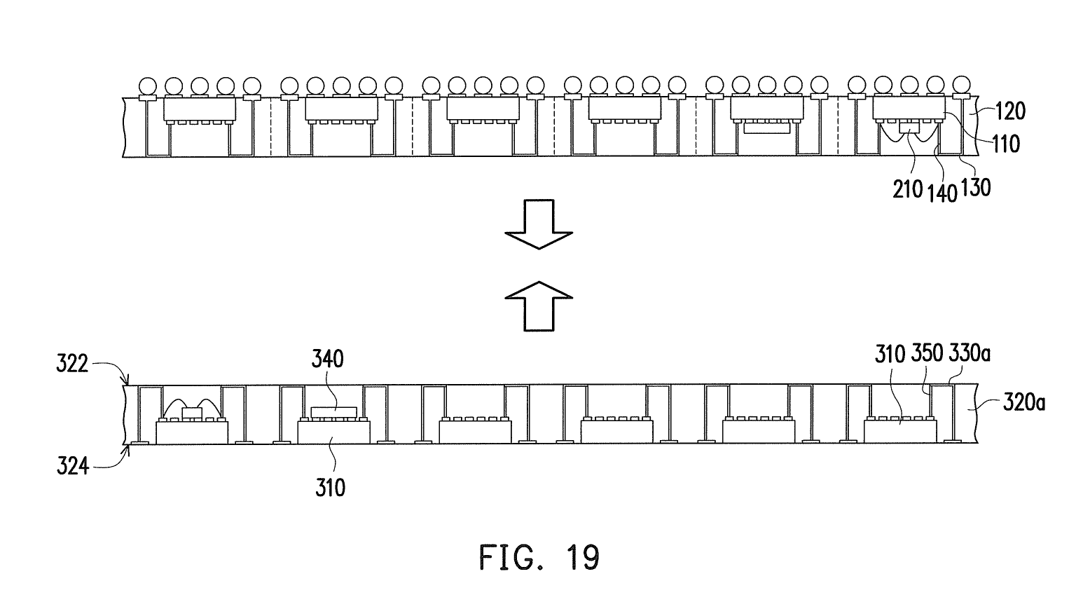

FIG. 19 is a schematic view illustrating a manufacturing method of a package structure according to an embodiment of the invention. According to an embodiment of the invention, as shown in FIG. 19, two selective-electroplating epoxy compounds 120 and 320a respectively encapsulate a plurality of chips 110, 210, 310 and 340. In addition, by using the selective-electroplating characteristic of the selective-electroplating epoxy compounds 120 and 320a, the selective-electroplating epoxy compounds 120 and 320a may be directly electroplated to form corresponding conductive vias and patterned circuit layers, so as to respectively electrically connect the chips 110, 210, 310, and 340 to surfaces of the selective-electroplating compounds 120 and 320a, thereby forming a first array package structure and a second array package structure shown in FIG. 19. Specifically speaking, the first array package structure at least includes the plurality of first chips 110, the first selective-electroplating epoxy compound 120, the plurality of first patterned circuit layers 130, and the plurality of conductive vias 140. The second array package structure at least includes the second chips 310, a plurality of second patterned circuit layers 330a, and a plurality of second conductive vias 350. The second selective-electroplating epoxy compound 320a covers the second chips 310. The second patterned circuit layers 330a are disposed on the fifth surface 322 of the second selective-electroplating epoxy compound 320a, and are respectively electrically connected to the corresponding second chips 310 through the corresponding second conductive vias 350. The selective-electroplating epoxy compounds 120 and 320a of the first array package structure and the second array package structure are then laminated together to electrically conduct the chips 110, 210, 310, and 340 by using the corresponding conductive vias 140 and 350 and the patterned circuit layers 130 and 330a. Then, the selective-electroplating epoxy compounds 120 and 320a are cut along broken lines to form a plurality of independent package structures.

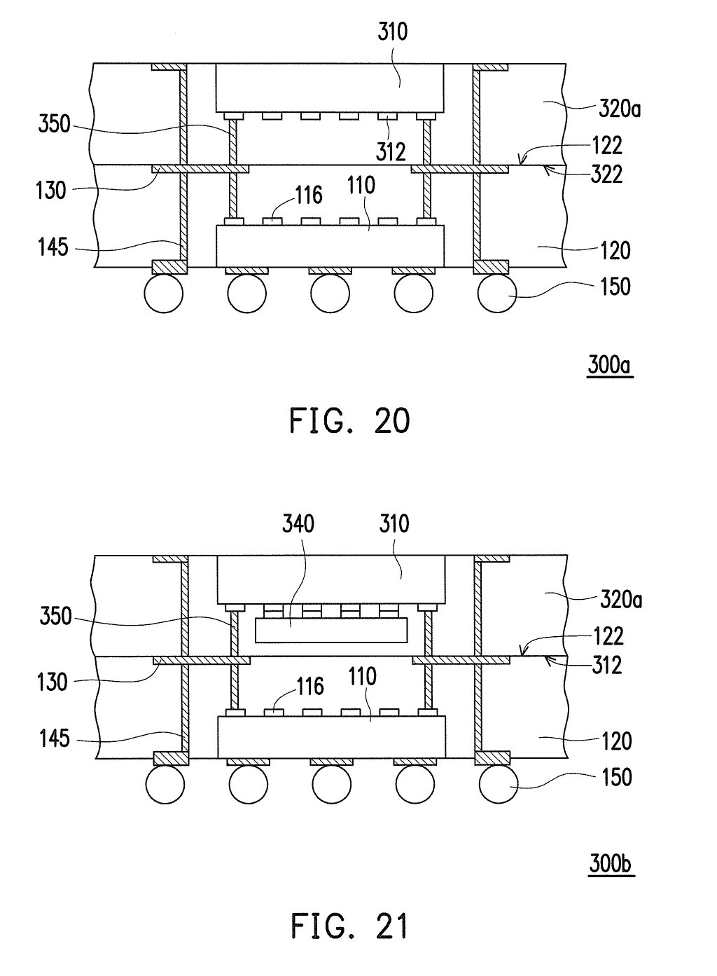

FIGS. 20-24 are cross-sectional schematic views illustrating package structures according to different embodiments of the invention. It should be noted that, as examples, FIGS. 20 to 24 are some package structures formed by using the manufacturing method shown in FIG. 19. Referring to FIG. 20, a package structure 300a of this embodiment further includes the first chip 110, the second chip 310, the first selective-electroplating epoxy compound 120, the second selective-electroplating epoxy compound 320a, and the plurality of fourth conductive vias 350. The first chip 110 includes the plurality of first solder pads 116, and the first selective-electroplating epoxy compound 120 covers the first chip 110. The second chip 310 includes a plurality of second solder pads 312. The second selective-electroplating epoxy compound 320a covers the second chip 310 and includes the fifth surface 322 connecting the third surface 122 of the first selective-electroplating epoxy compound 120.

The second selective-electroplating epoxy compound 320a and the first selective-electroplating epoxy compound 120 of this embodiment are substantially formed of the same material. Therefore, in this embodiment, the selective-electroplating characteristic of the second selective-electroplating epoxy compound 320a may be exploited for directly electroplating to form the fourth conductive vias 350 in the second selective-electroplating epoxy compound 320a, such that the fourth conductive vias 350 are directly disposed on the second selective-electroplating epoxy compound 320a to connect the second solder pads 312 to the fifth surface 322 and be electrically connected to the first patterned circuit layer 130 located on the third surface 122. Accordingly, the second chip 310 is electrically connected to the first patterned circuit layer 130 through the fourth conductive vias 350, and then electrically connected to the solder balls 150 through the third conductive vias 145. Thus, the first chip 110 and the second chip 310 may be electrically connected to the metal posts 180 of the interposer 105 through the solder balls 150.

Continuing to refer to FIG. 21, it should be noted that a package structure 300b of this embodiment is similar to the package structure 300a of FIG. 20. Therefore, the reference numerals and a part of the contents in the previous embodiment are used in the following embodiments, in which like reference numerals refer to like or similar elements, and repeated description of the same technical contents is omitted. For a detailed description of the omitted parts, reference can be made to the previous embodiment, and no repeated description is contained in the following embodiments. Description with respect to the difference between the package structure 300b of this embodiment and the package structure 300a of FIG. 20 is provided below. In this embodiment, the package structure 300b may further include the third chip 340. The third chip 340 is stacked on the second chip 310 in the face-to-face configuration and electrically connected to the second chip 310. Namely, the third chip 340 forms electrical connection with the second chip 310 by flip-chip bonding. The second selective-electroplating epoxy compound 320a also covers the third chip 340. Accordingly the third chip 340 may be electrically connected to the first patterned circuit layer 130 through the second chip 310 and the fourth conductive vias 350, and then electrically connected to the solder balls 150 through the third conductive vias 145. Then, the first chip 110, the second chip 310, and the third chip 340 may be electrically connected to the metal posts 180 of the interposer 105 through the solder balls 150, for example.

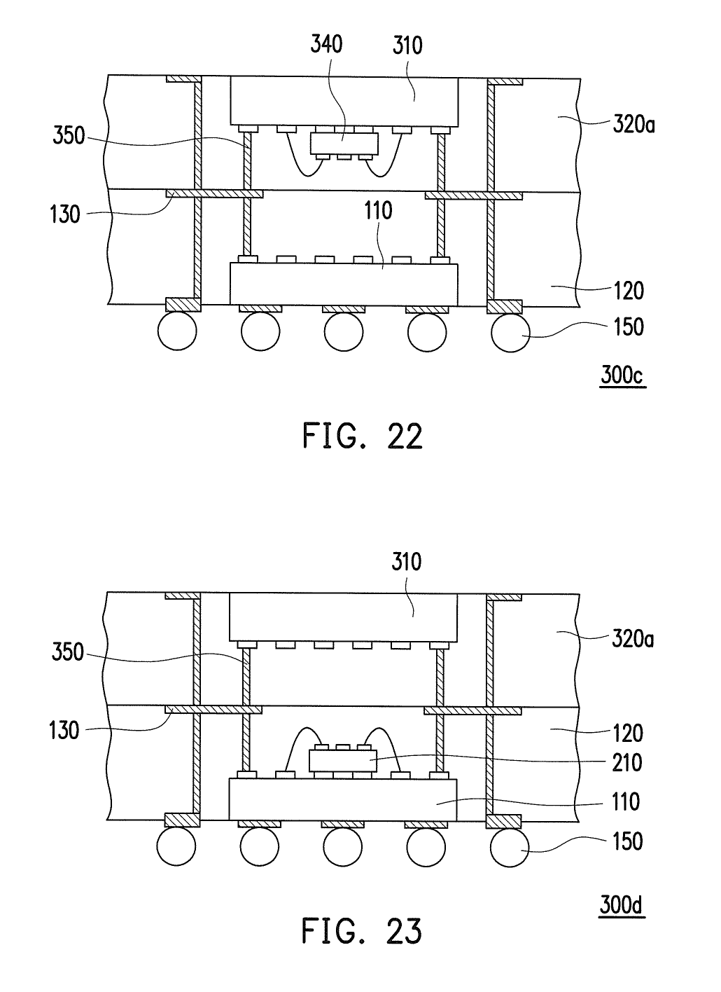

Continuing to refer to FIG. 22, it should be noted that a package structure 300c of this embodiment is similar to the package structure 300b of FIG. 21. Therefore, the reference numerals and a part of the contents in the previous embodiment are used in the following embodiments, in which like reference numerals refer to like or similar elements, and repeated description of the same technical contents is omitted. For a detailed description of the omitted parts, reference can be made to the previous embodiment, and no repeated description is contained in the following embodiments. Description with respect to the difference between the package structure 300c of this embodiment and the package structure 300b of FIG. 21 is provided below. Referring to FIG. 22, in this embodiment, the third chip 340 of the package structure 300c is also disposed on the second chip 310. However, the third chip 340 of this embodiment is electrically connected to the second chip 310 through wire bonding. The third selective-electroplating epoxy compound 310 also covers the third chip 340. Accordingly, the first chip 110, the second chip 310, and the third chip 340 may be electrically connected to the metal posts 180 of the interposer 105 through the solder balls 150, for example.

Continuing to refer to FIG. 23, a package structure 300d of this embodiment is similar to the package structure 300c of FIG. 22. Therefore, the reference numerals and a part of the contents in the previous embodiment are used in the following embodiments, in which like reference numerals refer to like or similar elements, and repeated description of the same technical contents is omitted. For a detailed description of the omitted parts, reference can be made to the previous embodiment, and no repeated description is contained in the following embodiments. Description with respect to the difference between the package structure 300d of this embodiment and the package structure 300c of FIG. 22 is provided below. Referring to FIG. 23, in this embodiment, the third chip 210 of the package structure 300d is also disposed on the first chip 110 and electrically connected to the first chip 110 by wire bonding. Also, the first selective-electroplating epoxy compound 120 also covers the third chip 210. Then, the first chip 110, the second chip 310, and the third chip 210 may be electrically connected to the metal posts 180 of the interposer 105 through the solder balls 150, for example.

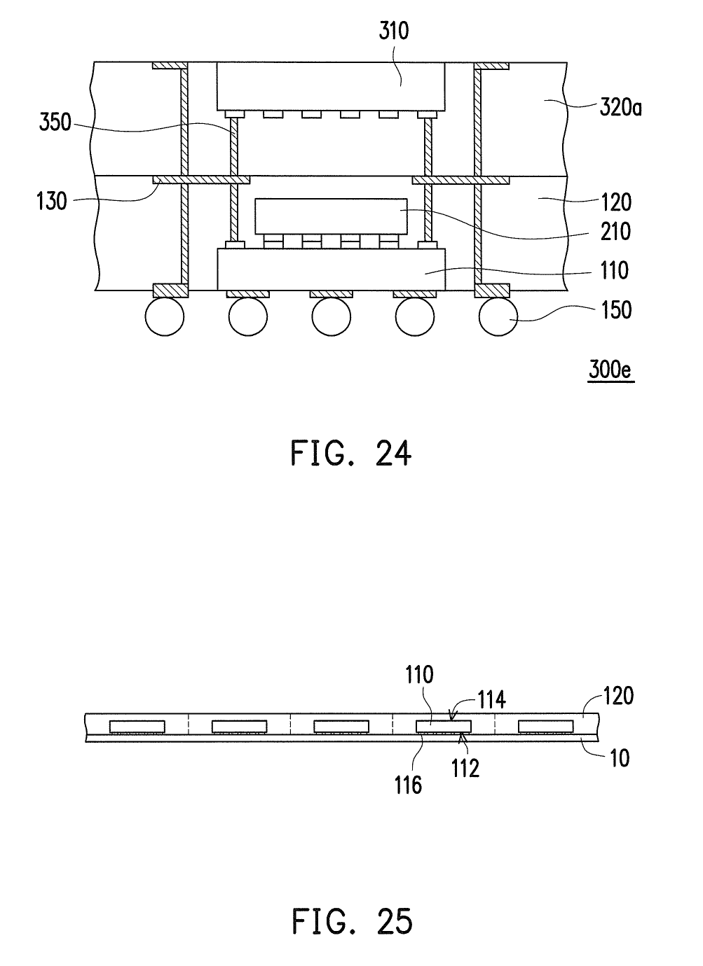

A package structure 300e of this embodiment shown in FIG. 24 is similar to the package structure 300d of FIG. 23. Therefore, the reference numerals and a part of the contents in the previous embodiment are used in the following embodiments, in which like reference numerals refer to like or similar elements and repeated description of the same technical contents is omitted. For a detailed description of the omitted parts, reference can be made to the previous embodiment, and no repeated description is contained in the following embodiments. Description with respect to the difference between the package structure 300e of this embodiment and the package structure 300d of FIG. 23 is provided below. Referring to FIG. 24, in this embodiment, the third chip 210 of the package structure 300e is stacked on the first chip 110 in the face-to-face configuration. In other words, the third chip 210 is electrically connected to the first chip 110 by flip-chip bonding. Besides, the first selective-electroplating epoxy compound 120 also covers the third chip 210 in addition to the first chip 110. Then, the first chip 110, the second chip 310, and the third chip 210 may be electrically connected to the metal posts 180 of the interposer 105 through the solder balls 150, for example.

FIG. 25 is a schematic view illustrating a manufacturing method of a package structure according to an embodiment of the invention. In an embodiment of the invention, the manufacturing method of the package structure may, as shown in FIG. 25, include disposing the plurality of first chips 110 on the release film 10 in advance. The first chip 110 includes the plurality of first solder pads 116, the active surface 112, and the back surface 114 opposite to the active surface 112. In addition, the first solder pads 116 are disposed on the active surface 112. The manufacturing method of this embodiment is similar to the manufacturing method of FIGS. 1A to 1D. However, the first chip 110 of this embodiment is adhered to the release film 10 with the active surface 112. Then, the release film 10 is stretched in the direction from the center to the periphery of the release film 10 to extend the release film 10, such that the first gap between any two adjacent chips 110 is extended to become the second gap, and the second gap is greater than the first gap. In other words, the gap between any two adjacent chips 110 is increased by stretching and extending the release film 10 for the convenience of the subsequent patterned circuit layer formation and singularization processes. Then, the plurality of first chips 110 are encapsulated by the first selective-electroplating epoxy compound 120 to cover the back surfaces 114 of the first chips 110 with the first selective-electroplating epoxy compound 120. Subsequently, by exploiting the characteristic that the first selective-electroplating epoxy compound 120 can be directly electroplated, a patterned circuit layer and a plurality of conductive vias are directly formed on the first selective-electroplating epoxy compound 120. Then, the release film 10 is removed to expose the first solder pads 116 and the active surface 112. Subsequently, the singularization process is performed. Namely, the first selective-electroplating epoxy compound 120 is cut along broken lines, for example, to form a plurality of independent package structures.

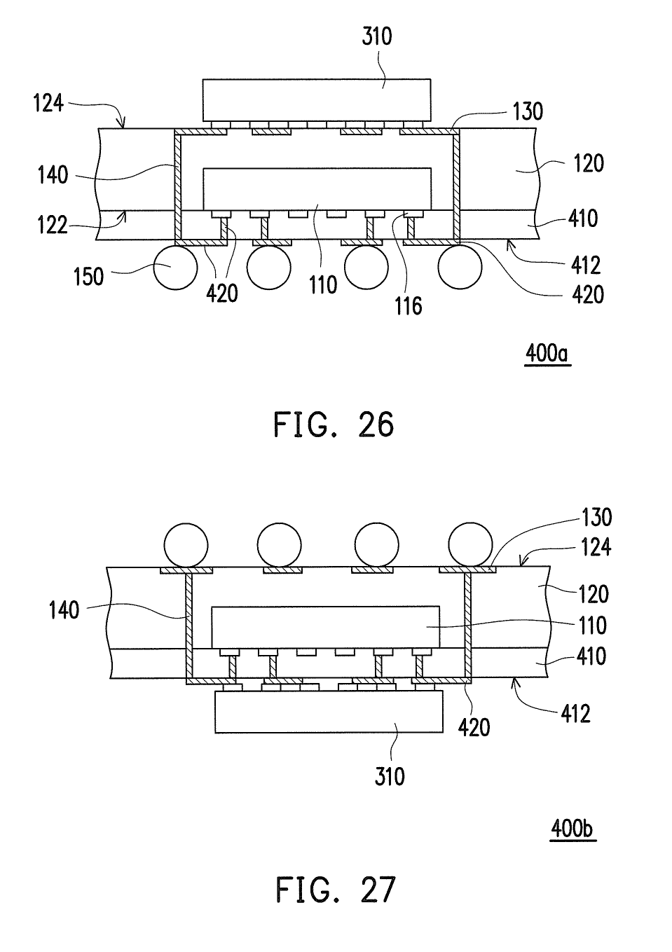

FIGS. 26-27 are cross-sectional schematic views illustrating package structures according to different embodiments of the invention. It should be noted that FIGS. 26 and 27 are some package structures adopting the structure manufactured by the manufacturing method shown in FIG. 25. Referring to FIG. 26, a package structure 400a further includes a dielectric layer 410, a redistribution circuit layer 420, and the second chip 310. The dielectric layer 410 is disposed on the third surface 122 of the first selective-electroplating epoxy compound 120 and covers the first solder pads 116 of the first chip 110. A material of the dielectric layer 410 in this embodiment may be the same as that of the selective-electroplating epoxy compound. Thus, the selective-electroplating characteristic of the dielectric layer 410 may be exploited to directly electroplate the dielectric layer 410, thereby directly forming the redistribution layer 420 on the dielectric layer 410 and electrically connecting the first solder pads 116 to an outer surface 412 of the dielectric layer 410. The redistribution circuit layer 420 shown in FIG. 26 may include a conductive post and a patterned circuit layer to electrically connect the first solder pads 116 to the outer surface 412 of the dielectric layer 410. Thus, complex processes in the conventional technology, which require to firstly dispose a dielectric layer, then to drill a conductive via by laser, sputter a metal seed layer, electroplate a metal layer and an under-bump metallization, and form a redistribution circuit layer by exposing, developing, and etching processes, etc., can now be simplified. Thus, this embodiment significantly simplifies manufacturing processes and reduces a manufacturing cost.

Based on the above, by exploiting the selective-electroplating characteristic of the first selective-electroplating epoxy compound 120 in this embodiment, selective-electroplating is directly performed on the fourth surface of the first selective-electroplating epoxy compound 120 to form the first patterned circuit layer 130, such that the first patterned circuit layer 130 is directly disposed on the fourth surface 124 of the first selective-electroplating epoxy compound 120, and the second chip 310 is disposed on the fourth surface 124 and is electrically connected to the first patterned circuit layer 130. In addition, the first conductive via 140 penetrates the first selective-electroplating epoxy compound 120 and the dielectric layer 410 to connect the first patterned circuit layer 130 and the redistribution circuit layer 420. Thus, the second chip 310 may be electrically connected to the redistribution circuit layer 420 located on the outer surface 412 of the dielectric layer 410 through a current conductive path formed by the first patterned circuit layer 130 and the first conductive vias 140. The solder balls 150 are disposed on the outer surface 412 and are electrically connected to the redistribution circuit layer 420. Then, the first chip 110 and the second chip 310 may be electrically connected to a motherboard or the metal posts 180 of the interposer 105 through the solder balls 150.

A package structure 400b of this embodiment shown in FIG. 27 is similar to the package structure 400a of FIG. 26. Therefore, the reference numerals and a part of the contents in the previous embodiment are used in the following embodiments, in which like reference numerals refer to like or similar elements and repeated description of the same technical contents is omitted. For a detailed description of the omitted parts, reference can be made to the previous embodiment, and no repeated description is contained in the following embodiments. Description with respect to the difference between the package structure 400b of this embodiment and the package structure 400a of FIG. 26 is provided below. Referring to FIG. 27, the second chip 310 of this embodiment is disposed on the outer surface 412 of the dielectric layer 410, and is electrically connected to the redistribution circuit layer 420. The first patterned circuit layer 130 is disposed on the fourth surface 124 of the first selective-electroplating epoxy compound 120. The first conductive via 140 penetrates the first selective-electroplating epoxy compound 120 to connect the redistribution circuit layer 420 and the first patterned circuit layer 130. The solder balls 150 are disposed on the fourth surface 124 and electrically connected to the first patterned circuit layer 130. Then, the first chip 110 and the second chip 310 may be electrically connected to the metal posts 180 of the interposer 105 through the solder balls 150.

In view of the foregoing, the embodiments of the invention exploit the selective-electroplating characteristic of the selective-electroplating epoxy compound, and are capable of forming conductive structures such as the patterned circuit layer and the conductive vias, etc. by directly performing electroplating on the surface of the selective-electroplating epoxy compound. In addition, the selective-electroplating epoxy compound includes non-conductive metal complex, therefore, after selectively irradiating the selective-electroplating epoxy compound by laser, electroplating process may be selectively performed on the surface of the selective-electroplating epoxy compound to form conductive structures such as the patterned circuit layer, conductive vias, or pads, etc. Moreover, the patterned circuit layer formed by selective-electroplating may be located coplanar with or below the surface of the selective-electroplating epoxy compound, or protruding from the surface of the selective-electroplating epoxy compound by thickening the patterned circuit layer through electroplating, so as to provide a greater electric flux. Therefore, the selective-electroplating epoxy compound is applicable for various kinds of package structures for forming a circuit layer on the selective-electroplating epoxy compound by exploiting the selective-electroplating characteristic thereof. Moreover, the patterned circuit layer not only meets the fine-pitch requirement, but also provides flexibility in designing circuits in the package structure. Thus, the package structure according to the embodiments of the invention is not only manufactured by a simplified manufacturing method, but also offers flexibility in designing the patterned circuit layer of the package structure. Moreover, the patterned circuit layer meets the fine-pitch requirement.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A package structure, comprising:
a first chip, comprising a plurality of first solder pads, an active surface, and a back surface opposite to the active surface, wherein the first solder pads are disposed on the active surface;
a first selective-electroplating epoxy compound, covering the active surface of the first chip and the first solder pads on the active surface and comprising non-conductive metal complex;
a first patterned circuit layer, directly disposed on a surface of the first selective-electroplating epoxy compound, wherein the first selective-electroplating epoxy compound exposes an upper surface of the patterned circuit layer, and the upper surface is lower than or coplanar with the surface of the first selective-electroplating epoxy compound; and
a plurality of first conductive vias, disposed in the first selective-electroplating epoxy compound to electrically connect the first solder pads to the first patterned circuit layer.

2. The package structure as claimed in claim 1, wherein the non-conductive metal complex comprises a palladium, chromium, or copper complex.

3. The package structure as claimed in claim 1, wherein the first selective-electroplating epoxy compound is adapted to be selective irradiated by laser to selectively metalize the non-conductive metal complex.

4. The package structure as claimed in claim 1, further comprising an interposer, wherein the interposer comprises:
a second selective-electroplating epoxy compound, comprising a plurality of cavities, a first surface, and a second surface opposite to the first surface, wherein the cavities are disposed on the first surface, and the second selective-electroplating epoxy compound comprises non-conductive metal complex;
a second patterned circuit layer, directly disposed on the first surface;
a plurality of metal posts, respectively disposed in the cavities and protruding form the first surface, wherein the second patterned circuit layer is electrically connected to the corresponding metal posts, and the first chip is electrically connected to the metal posts;
a plurality of pads, directly disposed on the second surface; and
a plurality of second conductive vias, disposed in the second selective-electroplating epoxy compound to electrically connect the pads to the corresponding metal posts.

5. The package structure as claimed in claim 4, further comprising:
a plurality of solder balls, disposed on the metal posts, wherein the first chip is electrically connected to the interposer through the metal posts.

6. The package structure as claimed in claim 1, further comprising a shielding metal layer, directly and covering an outer surface of the first selective-electroplating epoxy compound.

7. The package structure as claimed in claim 6, wherein the shielding metal layer is connected to a ground electrode.

8. The package structure as claimed in claim 1, wherein the first selective-electroplating epoxy compound comprises a third surface and a fourth surface opposite to each other, and covers the active surface and the first solder pads of the first chip, the first conductive vias connect the first solder pads to the third surface, and the first patterned circuit layer is directly disposed on the third surface.

9. The package structure as claimed in claim 8, further comprising:
a plurality of solder balls, disposed on the third surface and electrically connected to the first patterned circuit layer.

10. The package structure as claimed in claim 9, further comprising:
a second chip, disposed on the third surface and electrically connected to the first patterned circuit layer, wherein the second chip is located between the solder balls.

11. The package structure as claimed in claim 8, further comprising:
a plurality of third conductive vias, penetrating the first selective-electroplating epoxy compound to connect the fourth surface and the first patterned circuit layer located on the third surface;
a second chip, disposed on the fourth surface and electrically connected to the third conductive vias and the corresponding second patterned circuit layer through a plurality of wires; and
an encapsulant, covering the second chip and the wires.

12. The package structure as claimed in claim 8, further comprising a second chip comprising a plurality of second solder pads, wherein the second chip is disposed on the active surface of the first chip and is electrically connected with the first solder pads through the second solder pads, and the first selective-electroplating epoxy compound covers the second chip.

13. The package structure as claimed in claim 8, further comprising a second chip disposed on the active surface of the first chip and is electrically connected to at least a part of the first solder pads through a plurality of wires, wherein the first selective-electroplating epoxy compound covers the second chip and the wires, and the first conductive vias connect the rest of the first solder pads to the third surface.

14. The package structure as claimed in claim 8, wherein the first patterned circuit layer is directly disposed on the third surface and electrically connected with the first conductive vias, and the package structure further comprises:
a third patterned circuit layer, directly disposed on the fourth surface;
a plurality of third conductive vias, penetrating the first selective-electroplating epoxy compound to connect the first patterned circuit layer and the third patterned circuit layer; and
a plurality of solder balls, disposed on the fourth surface and electrically connected to the third patterned circuit layer.

15. The package structure as claimed in claim 14, further comprising:
at least one second chip, disposed on the third surface and electrically connected to the first patterned circuit layer.

16. The package structure as claimed in claim 15, further comprising:
a third selective-electroplating epoxy compound, covering the at least one second chip.

17. The package structure as claimed in claim 16, wherein the third selective-electroplating epoxy compound comprises a fifth surface opposite to a surface of the third selective-electroplating epoxy compound covering the third surface, and the package structure further comprises:
a plurality of fourth conductive vias, penetrating the third selective-electroplating epoxy compound and electrically connecting the first patterned circuit layer to the fifth surface.

18. The package structure as claimed in claim 17, further comprising: at least one third chip, disposed on the fifth surface and electrically connected to the fourth conductive vias.

19. The package structure as claimed in claim 14, further comprising:
at least one second chip, disposed on the fourth surface and electrically connected to the third patterned circuit layer.

20. The package structure as claimed in claim 19, further comprising:
a third selective-electroplating epoxy compound, covering the at least one second chip and the fourth surface.

21. The package structure as claimed in claim 20, wherein the third selective-electroplating epoxy compound comprises a fifth surface opposite to a surface of the third selective-electroplating epoxy compound covering the fourth surface, and the package structure further comprises:
a plurality of fourth conductive vias, penetrating the third selective-electroplating epoxy compound to electrically connect the third patterned circuit layer to the fifth surface.

22. The package structure as claimed in claim 21, further comprising:
at least one third chip, disposed on the fifth surface and electrically connected to the fourth conductive vias.

23. The package structure as claimed in claim 20, further comprising:
at least one third chip, disposed on the active surface of the first chip and electrically connected to the first solder pads, wherein the first selective-electroplating epoxy compound covers the third chip.

24. The package structure as claimed in claim 14, further comprising:
a second chip, comprising a plurality of second solder pads;
a third selective-electroplating epoxy compound, covering the second chip and the second solder pads and comprising a fifth surface, wherein the fifth surface is connected to the third surface of the first selective-electroplating epoxy compound; and
a plurality of fourth conductive vias, directly disposed in the third selective-electroplating epoxy compound to connect the second solder pads to the fifth surface and electrically connected to the first patterned circuit layer.

25. The package structure as claimed in claim 24, further comprising:
a third chip, disposed on the second chip and electrically connected to the second solder pads, wherein the third selective-electroplating epoxy compound covers the third chip.

26. The package structure as claimed in claim 24, further comprising:
a third chip, disposed on the active surface of the first chip and electrically connected to the first solder pads, wherein the first selective-electroplating epoxy compound covers the third chip.

27. The package structure as claimed in claim 1, wherein the first selective-electroplating epoxy compound comprises a third surface and a fourth surface opposite to each other, and covers the back surface of the first chip, and exposes the first solder pads.

28. The package structure as claimed in claim 27, further comprising:
a dielectric layer, disposed on a third surface of the first selective-electroplating epoxy compound and covering the first solder pads; and
a redistribution circuit layer, disposed on the dielectric layer and electrically connecting the first solder pads to an outer surface of the dielectric layer.

29. The package structure as claimed in claim 28, wherein the dielectric layer is a selective-electroplating epoxy compound.

30. The package structure as claimed in claim 28, wherein the first patterned circuit layer is directly disposed on a fourth surface of the first selective-electroplating epoxy compound opposite to the third surface, the first conductive vias penetrate the first selective-electroplating epoxy compound and the dielectric layer to connect the first patterned circuit layer and the redistribution circuit layer, and the package structure further comprises:
a second chip, disposed on the fourth surface and electrically connected to the first patterned circuit layer; and
a plurality of solder balls, disposed on the outer surface and electrically connected to the redistribution circuit layer.

31. The package structure as claimed in claim 28, wherein the first patterned circuit layer is directly disposed on a fourth surface of the first selective-electroplating epoxy compound opposite to the third surface, the first conductive vias penetrate the first selective-electroplating epoxy compound and the dielectric layer to connect the first patterned circuit layer and the redistribution circuit layer, and the package structure further comprises:
a second chip, disposed on the outer surface of the dielectric layer and electrically connected to the redistribution circuit layer; and
a plurality of solder balls, disposed on the fourth surface and electrically connected to the first patterned circuit layer.

32. A manufacturing method of a package structure, comprising:
disposing a plurality of chips on a release film, wherein a first gap exists between any two adjacent chips;
stretching the release film in a direction from the center to the periphery of the release film to extend the release film, wherein a second gap exists between any two adjacent chips, and the second gap is greater than the first gap;
forming a selective-electroplating epoxy compound on the release film to cover the chips;
forming a first patterned circuit layer and a plurality of conductive vias on the selective-electroplating epoxy compound by using laser and an electroplating process, wherein the patterned circuit layer is located on a surface of the selective-electroplating epoxy compound, and is electrically connected to the chip through the conductive vias to form a plurality of package structures connected to each other; and
singularizing the package structures to form a plurality of independent package structures.

33. The manufacturing method of the package structure as claimed in claim 32, wherein each of the chips comprises a plurality of solder pads, an active surface, and a back surface opposite to the active surface, the solder pads are disposed on the active surface, each of the chips is disposed on the release film with the back surface of the chip, and the selective-electroplating epoxy compound covers the active surface and the solder pads.

34. The manufacturing method of the package structure as claimed in claim 32, wherein each of the chips comprises a plurality of solder pads, an active surface, and a back surface opposite to the active surface, the solder pads are disposed on the active surface, each of the chips is disposed on the release film with the active surface of the chip, and the selective-electroplating epoxy compound covers the back surface and the solder pads.
